(19) United States
(12) Patent Application Publication
(10) Pub. No.: US 2015/0136364 A1
(43) Pub. Date: May 21, 2015

(54) HEAT DISSIPATION DEVICE

(71) Applicant: Chih-Hong Chuang, Hsinchu County (TW)

(72) Inventor: Chih-Hong Chuang, Hsinchu County (TW)

(73) Assignee: SUBTRON TECHNOLOGY CO., LTD., Hsinchu County (TW)

(21) Appl. No.: 14/153,096

(22) Filed: Jan. 13, 2014

(30) Foreign Application Priority Data
Nov. 21, 2013 (TW) 102142506

(51) Int. Cl. H01L 33/64

(52) U.S. Cl. CPC H01L 33/648
USPC 165/104.31

(57) ABSTRACT

A heat dissipation device includes a package carrier, heat dissipating fins, an atomizer and a driving unit. The package carrier has a carrying surface and a disposing surface divided into a first region and a second region. The heat dissipating fines are located in the second region and define an accommodating space with the package carrier. An extending direction of the heat dissipating fines is perpendicular to an extending direction of the package carrier. The atomizer is disposed on the heat dissipating fines and located in the accommodating space. The atomizer includes an atomization unit, a liquid containing cavity and a fluid channel. The liquid containing cavity, the heat dissipating fines and the package carrier define a fluid chamber. The driving unit is electrically connected to the atomizer so as to drive a working fluid to the atomization unit and atomize the working fluid into an atomization micro-mist.

### CROSS-REFERENCE TO RELATED APPLICATION

This application claims the priority benefit of Taiwan application serial no. 102142506, filed on Nov. 21, 2013. The entirety of the above-mentioned patent application is hereby incorporated by reference herein and made a part of this specification.

### BACKGROUND OF THE INVENTION

1. Field of the Invention

The present invention relates to a heat dissipation device, and more particularly to a heat dissipation device which can be provided to a heat generation element for heat dissipation.

2. Description of Related Art

In general, when the light emitting diode (LED) emits lights with high luminance, it generates high thermal energy. If the thermal energy cannot be transmitted away and keeps on accumulating within the LED, the temperature of the LED is continuously increased. Therefore, the over heated LED leads to the luminance of the LED fading away and the decreasing of the lifetime of the LED and even the permanent damage of the LED. Hence, in order to prevent the LED from being over heated and temporarily or permanently losing effectiveness, the current illumination using the LEE) is equipped with the heat sink to decrease the working temperature thereof so as to maintain the LED in a proper operation.

### SUMMARY OF THE INVENTION

The present invention provides a heat dissipation device which has better heat dissipating efficiency.

The heat dissipation device of the invention includes a package carrier, a plurality of heat dissipating fins, an atomizer and a driving unit. The package carrier has a carrying surface and a disposing surface opposite to each other. The disposing surface is divided into a first region and a second region surrounding the first region. The heat dissipating fins are disposed on the package carrier and located in the second region of the disposing surface. The heat dissipating fins and the package carrier define an accommodating space. An extending direction of the heat dissipating fins is perpendicular to an extending direction of the package carrier. The atomizer is disposed on the heat dissipating fins and located in the accommodating space. The atomizer includes an atomization unit, a liquid containing cavity and a fluid channel connected to the liquid containing cavity. The liquid containing cavity, the heat dissipating fins, and the package carrier define a fluid chamber. The atomization unit is connected to the liquid containing cavity and a working fluid is stored in the liquid containing cavity. The driving unit is electrically connected to the atomizer, so that the working fluid is driven to the atomization unit and atomized into an atomization micro-mist. The atomization micro-mist flows in the fluid chamber, and flows back to the liquid containing cavity through the fluid channel.

According to an exemplary embodiment of the present invention, the first region of the disposing surface has a lumpy surface structure.

According to an exemplary embodiment of the present invention, the heat dissipating fins include a plurality of first heat dissipating fins and a plurality of second heat dissipating fins. The first heat dissipating fins surround a periphery of the first region, the second heat dissipating fins surround the first heat dissipating fins, and the first heat dissipating fins and the package carrier define the accommodating space.

According to an exemplary embodiment of the present invention, the heat dissipating fins further include a plurality of first connecting portions and a plurality of second connecting portions. The first connecting portions are connected between the first heat dissipating fins and the second heat dissipating fins The second connecting portions are connected between the second heat dissipating fins.

According to an exemplary embodiment of the present invention, the heat dissipation device further includes a plurality of fixing elements disposed between the first heat dissipating fins and the atomizer, so that the atomizer is fixed on the first heat dissipating fins.

According to an exemplary embodiment of the present invention, the extending direction of the heat dissipating fins is horizontal, the atomizer is located at a side of the package carrier, and the atomization micro-mist is ejected from left side to right side or ejected from right side to left side.

According to an exemplary embodiment of the present invention, the liquid containing cavity has a liquid inlet and a liquid outlet. The liquid inlet and the liquid outlet are opposite to each other and located outside the accommodating space.

According to an exemplary embodiment of the present invention, the atomizer further includes a recycling containing cavity connected to the liquid containing cavity and having a liquid inlet, a liquid outlet, a recycling inlet and a recycling outlet. The recycling inlet is connected to the fluid channel, the recycling outlet is connected to the liquid containing cavity, and the liquid inlet is located nearer to the recycling outlet than the liquid outlet is.

According to an exemplary embodiment of the present invention, the atomizer is located beneath the package carrier, and the atomization micro-mist is ejected from bottom to top.

According to an exemplary embodiment of the present invention, the atomizer is located above the package carrier, and the atomization micro-mist is ejected from top to bottom.

In light of the above, the heat dissipation device of the present invention is provided with heat dissipating fins and an atomizer. Consequently, heat can be passively dissipated by the heat dissipating fins and actively dissipated by the atomization micro-mist generated by the atomizer. Therefore, if a heat generation element (e.g., an LED chip, a power amplifier, or a power integrated circuit (IC)) is disposed on the carrying surface of the package carrier in the follow-up process, the heat dissipation device of the present invention can effectively decrease the working temperature of the heat generation element, and a better heat dissipating effect can be achieved.

Several exemplary embodiments accompanied with figures are described in detail below to further describe the invention in details.

### BRIEF DESCRIPTION OF THE DRAWINGS

The accompanying drawings constituting a part of this specification are incorporated herein to provide a further understanding of the disclosure. Here, the drawings illustrate embodiments of the disclosure and, together with the description, serve to explain the principles of the disclosure.

FIG. 1 is a schematic view illustrating a heat dissipation device according to one exemplary embodiment of the present invention.

FIG. 2 is a schematic view illustrating a heat dissipation device according to another exemplary embodiment of the present invention.

FIG. 3 is a schematic view illustrating a heat dissipation device according to another exemplary embodiment of the present invention.

FIG. 4 is a schematic view illustrating a heat dissipation device according to another exemplary embodiment of the present invention.

### DESCRIPTION OF EMBODIMENTS

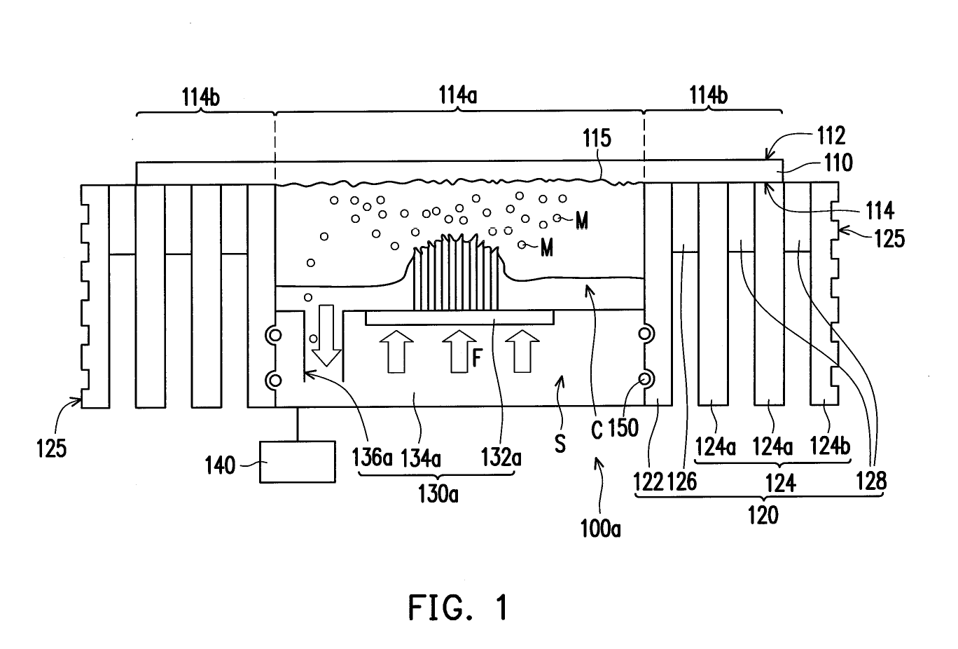

FIG. 1 is a schematic view illustrating a heat dissipation device according to one exemplary embodiment of the present invention. Referring to FIG. 1, in the embodiment, the heat dissipation device 100a includes a package carrier 110, a plurality of heat dissipating fins 120, an atomizer 130a and a driving unit 140. The package carrier 110 has a carrying surface 112 and a disposing surface 114 opposite to each other. The disposing surface 114 is divided into a first region 114a and a second region 114b surrounding the first region 114a. The heat dissipating fins 120 are disposed on the package carrier 110 and located in the second region 114b of the disposing surface 114. The heat dissipating fins 120 and the package carrier 110 define an accommodating space S. An extending direction of the heat dissipating fins 120 is perpendicular to an extending direction of the package carrier 110. The atomizer 130a is disposed on the heat dissipating fins 120 and located in the accommodating space S. The atomizer 130a includes an atomization unit 132a, a liquid containing cavity 134a and a fluid channel 136a connected to the liquid containing cavity 134a. The liquid containing cavity 134a, the heat dissipating fins 120, and the package carrier 110 define a fluid chamber C. The atomization unit 132a is connected to the liquid containing cavity 134a and a working fluid F is stored in the liquid containing cavity 134a. The driving unit 140 is electrically connected to the atomizer 130a, so that the working fluid F is driven to the atomization unit 132a and atomized into an atomization micro-mist M. The atomization micro-mist M flows in the fluid chamber C, and flows back to the liquid containing cavity 134a through the fluid channel 136a. Herein the atomization unit 132a is a piezoelectric material element, for example.

More specifically, in the embodiment, the package carrier 110 is composed of a multi-layer patterned conductive layer (not shown) and at least an insulating layer (not shown) for example, wherein the insulating layer is disposed between the adjacent patterned conductive layers so as to achieve insulating effect. Or, for example, the package carrier 110 is a metal substrate, and the structure and type of the package carrier 110 is not limited thereto. Especially, the first region 114a of the disposing surface 114 of the package carrier 110 has a lumpy surface structure 115, in order to increase the contact area between the disposing surface 114 and the atomization micro-mist M, so that the working temperature of a heat generation element (not shown) disposed on the package carrier 112 in the follow-up process can be effectively reduced.

In addition, the heat dissipating fins 120 of the embodiment may specifically include a plurality of first heat dissipating fins 122 and a plurality of second heat dissipating fins 124. The first heat dissipating fins 122 surround a periphery of the first region 114a of the disposing surface 114, the second heat dissipating fins 124 surround the first heat dissipating fins 122, and the first heat dissipating fins 122 and the package carrier 110 define the accommodating space S. In more detailed, the second heat dissipating fins 124 may be divided into a plurality of second sub heat dissipating fins 124a and a plurality of second sub heat dissipating fins 124b, wherein the second sub heat dissipating fins 124a surround the first heat dissipating fins 122, the structure of the second sub heat dissipating fins 124a and the structure of the first heat dissipating fins 122 are substantially the same, namely are in stripe shapes. On the other hand, the second sub heat dissipating fins 124b surround the second sub heat dissipating fins 124a and extend to the outside of the package carrier 110, wherein the side surfaces 125 of the second sub heat dissipating fins 124b which are comparatively away from the second sub heat dissipating fins 124a are lumpy surfaces, so as to increase heat dissipating area.

Additionally, the heat dissipating fins 120 of the embodiment further include a plurality of first connecting portions 126 and a plurality of second connecting portions 128, the first connecting portions 126 are connected between the first heat dissipating fins 122 and the second sub heat dissipating fins 124a of the second heat dissipating fins 124. The second connecting portions 128 are connected between the second sub heat dissipating fins 124a and the second sub heat dissipating fins 124a of the second heat dissipating fins 124, and between the second sub heat dissipating fins 124a and the second sub heat dissipating fins 124b of the second heat dissipating fins 124. Moreover, the heat dissipation device 100a of the embodiment further includes a plurality of fixing elements 150 disposed between the first heat dissipating fins 122 and the atomizer 130a, so that the atomizer 130a is fixed on the first heat dissipating fins 122. As shown in FIG. 1, specifically, the atomizer 130a is located right beneath the package carrier 110, and the atomization micro-mist M is ejected from bottom to top.

When the driving unit 140 drives the working fluid F (e.g., cooling liquid) to the atomization unit 132a, the atomization unit 132a may couple a vibration energy into the working fluid F because of principle of piezoelectric vibration, and capillary waves may be generated on the surface of the working fluid F, and the working fluid F may flow in the fluid chamber C in the form of atomization micro-mist M. In other words, the atomization unit 132a generates vibration due to the principle of piezoelectric transform, so that the working fluid F is oscillated into the atomization micro-mist M. In this tune, the atomization micro-mist M flowing in the fluid chamber C may dissipate the working temperature of the heat generation element (not shown) located on the carrying surface 112 through heat convection, and actively heat dissipating effect can be achieved. In addition, the atomization micro-mist M may also flows back to the liquid containing cavity 134a through the fluid channel 136a due to gravity, then a cooling recycling system which is continuously circulated is formed.

The heat dissipation device 100a of the embodiment is provided with the heat dissipating fins 120 and the atomizer 130a. Consequently, heat can be passively dissipated by the heat dissipating fins 120 and actively dissipated by the atomization micro-mist M generated by the atomizer 130a. Therefore, if a heat generation element (e.g., an LED chip, a power amplifier, or a power integrated circuit (IC)) is to be disposed on the carrying surface 112 of the package carrier 110 in the follow-up process, the heat dissipation device 100a of the embodiment can effectively reduce the working temperature of the heat generation element, and a better heat dissipating effect can be achieved.

Several embodiments that illustrate the structures of the heat dissipation devices 100b, 100c, and 100d are described as follows. It should be mentioned that the exemplary embodiments provided below adopt notations and partial content of the exemplary embodiment aforementioned. Herein, identical notations are used to denote identical or similar elements and the description of identical technology is omitted. The omitted part can be referred to the above exemplary embodiment and is not repeated hereinafter.

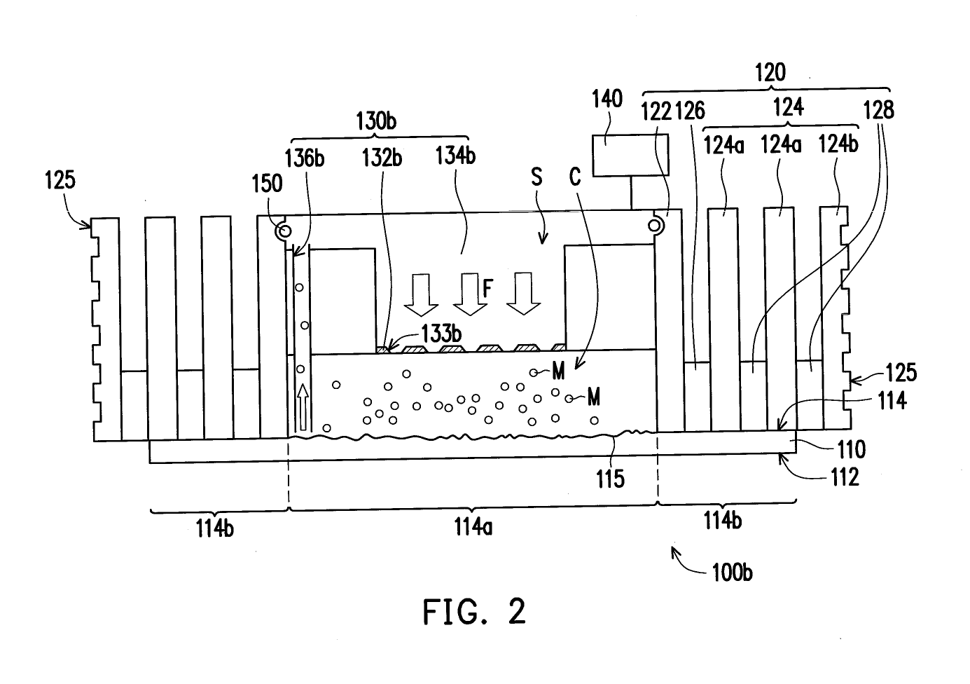

FIG. 2 is a schematic view illustrating a heat dissipation device according to another exemplary embodiment of the present invention. Referring to FIG. 2, the heat dissipation device 100b of the present embodiment is similar to the heat dissipation device 100a of FIG. 1. The main difference is that the atomizer 130b of the present embodiment is located above the package carrier 110 substantially, and the atomization micro-mist M is ejected from top to bottom. More specifically, the atomization unit 132b of the atomizer 130b of the embodiment is specifically an atomization thin film 132b, wherein the atomization thin film 132b has a plurality of micro-openings 133b, and the diameter of each of the micro-openings 133b is gradually getting smaller from the adjacent liquid cavity 134b toward the package carrier 110. As shown in FIG. 2, the atomization micro-mist M may flow back to the liquid containing cavity 134b through the fluid channel 136b due to capillary phenomenon.

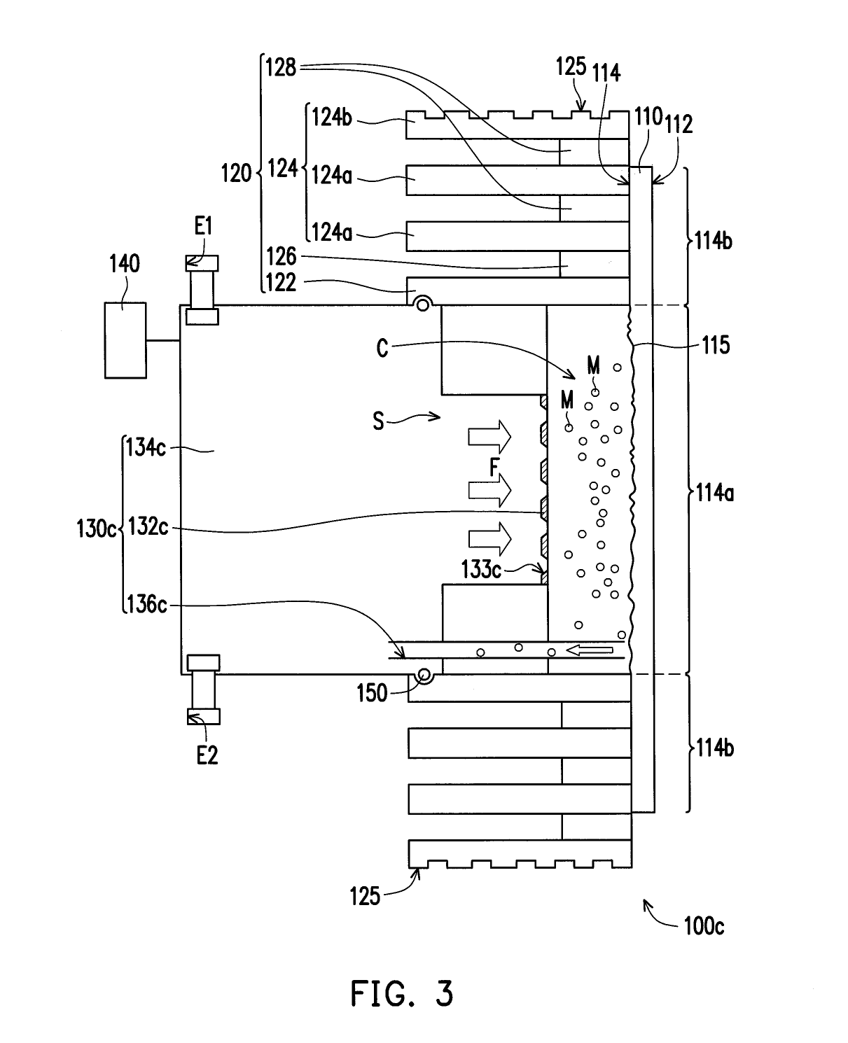

FIG. 3 is a schematic view illustrating a heat dissipation device according to another exemplary embodiment of the present invention. Referring to FIG. 3, the heat dissipation device 100c of the present embodiment is similar to the heat dissipation device 100a of FIG. 1. The main difference is that the extending direction of the heat dissipating fins 120 is substantially in a horizontal direction, the atomizer 130c is located at a side of the package carrier 110, at the left side as shown in FIG. 3, and the atomization micro-mist M is ejected from left side to right side. Of course, in other exemplary embodiments which are not shown in figures, the atomizer may also be located at the right side of the package carrier, and the atomization micro-mist is ejected from right side to left side.

In addition, in the embodiment, a portion of the liquid containing cavity 134c of the atomizer 130c extends outside the accommodating space S, and the liquid containing cavity 134c has a liquid inlet E1 and a liquid outlet E2, wherein the liquid inlet E1 and the liquid outlet E2 are opposite to each other and located outside the accommodating space S. In other words, the atomizer 130c is configured in a manner that only the atomization unit 132c and the fluid channel 136c are located within the accommodating space S. Herein, the atomization unit 132c of the atomizer 130c is specifically an atomization thin film 132c, wherein the atomization thin film 132c has a plurality of micro-openings 133c, and the diameter of each of the micro-openings 133c is gradually getting smaller from the adjacent liquid cavity 134c toward the package carrier 110. As shown in FIG. 3, the atomization micro-mist M may flow back to the liquid containing cavity 134c through the fluid channel 136c due to capillary phenomenon.

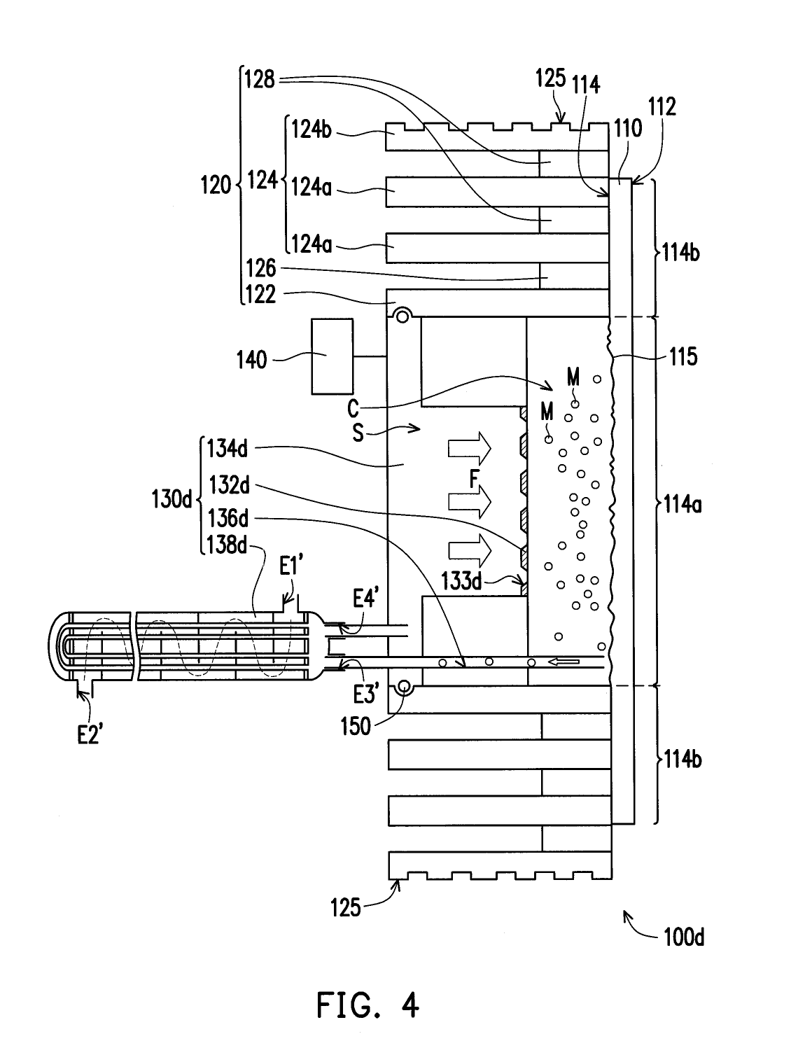

FIG. 4 is a schematic view illustrating a heat dissipation device according to another exemplary embodiment of the present invention. Referring to FIG. 4, the heat dissipation device 100d of the present embodiment is similar to the heat dissipation device 100c of FIG. 3. The main difference is that the atomizer 130d of the present embodiment includes a recycling containing cavity 138d which is connected to the liquid containing cavity 134d and has a liquid inlet E1′, a liquid outlet E2′, a recycling inlet E3′ and a recycling outlet E4′. The recycling inlet E3′ is connected to the fluid channel 136d, the recycling outlet E4′ is connected to the liquid containing cavity 134d, and the liquid inlet E1′ is located nearer to the recycling outlet E4′ than the liquid outlet E2′ is. Herein all of the atomization unit 132d, the liquid containing cavity 134d and the fluid channel 136d of the atomizer 130d are located in the accommodating space S, and only the recycling containing cavity 138d is located outside the accommodating space S.

In light of the foregoing, the heat dissipation device of the present invention is provided with heat dissipating fins and an atomizer. Consequently, heat can be passively dissipated by the heat dissipating fins, and actively dissipated by the atomization micro-mist generated by the atomizer. Therefore, if a heat generation element (e.g., an LED chip, a power amplifier, or a power integrated circuit (IC)) is disposed on the carrying surface of the package carrier in the follow-up process, the heat dissipation device of the present invention can effectively decrease the working temperature of the heat generation element, and a better heat dissipating effect can be achieved.

It will be apparent to those skilled in the art that various modifications and variations can be made to the structure of the disclosed embodiments without departing from the scope or spirit of the invention. In view of the foregoing, it is intended that the disclosure cover modifications and variations of this specification provided they fall within the scope of the following claims and their equivalents.

What is claimed is:

1. A heat dissipation device, comprising:
a package carrier, having a carrying surface and a disposing surface opposite to each other, wherein the disposing surface is divided into a first region and a second region surrounding the first region;
a plurality of heat dissipating fins, disposed on the package carrier and located in the second region of the disposing surface, wherein the heat dissipating fins and the package carrier define an accommodating space, and an extending direction of the heat dissipating fins is perpendicular an extending direction of the package carrier;
an atomizer, disposed on the heat dissipating fins and located in the accommodating space, the atomizer comprising an atomization unit, a liquid containing cavity and a fluid channel connected to the liquid containing cavity, wherein the liquid containing cavity, the heat dissipating fins and the package carrier define a fluid chamber, the atomization unit is connected to the liquid containing cavity, and a working fluid is stored in the liquid containing cavity; and
a driving unit, electrically connected to the atomizer so that the working fluid is driven to the atomization unit and atomized into an atomization micro-mist, wherein the atomization micro-mist flows in the fluid chamber and flows back to the liquid containing cavity through the fluid channel.

2. The heat dissipation device as claimed in claim 1, wherein the first region of the disposing surface has a lumpy surface structure.

3. The heat dissipation device as claimed in claim 1, wherein the heat dissipating fins comprise a plurality of first heat dissipating fins and a plurality of second heat dissipating fins, the first heat dissipating fins surround a periphery of the first region, the second heat dissipating fins surround the first heat dissipating fins, and the first heat dissipating fins and the package carrier define the accommodating space.

4. The heat dissipation device as claimed in claim 3, wherein the heat dissipating fins further comprise a plurality of first connecting portions and a plurality of second connecting portions, the first connecting portions are connected between the first heat dissipating fins and the second heat dissipating fins, and the second connecting portions are connected between the second heat dissipating fins.

5. The heat dissipation device as claimed in claim 3, further comprising:
a plurality of fixing elements, disposed between the first heat dissipating fins and the atomizer, so that the atomizer is fixed on the first heat dissipating fins.

6. The heat dissipation device as claimed in claim 1, wherein the extending direction of the heat dissipating fins is horizontal, the atomizer is located at a side of the package carrier, and the atomization micro-mist is ejected from left side to right side or ejected from right side to left side.

7. The heat dissipation device as claimed in claim 6, wherein the liquid containing cavity has a liquid inlet and a liquid outlet, and the liquid inlet and the liquid outlet are opposite to each other and located outside the accommodating space.

8. The heat dissipation device as claimed in claim 6, wherein the atomizer further comprises a recycling containing cavity connected to the liquid containing cavity and having a liquid inlet, a liquid outlet, a recycling inlet and a recycling outlet, the recycling inlet is connected to the fluid channel, the recycling outlet is connected to the liquid containing cavity, and the liquid inlet is located nearer to the recycling outlet than the liquid outlet is.

9. The heat dissipation device as claimed in claim 1, wherein the atomizer is located beneath the package carrier, and the atomization micro-mist is ejected from bottom to top.

10. The heat dissipation device as claimed in claim 1, wherein the atomizer is located above the package carrier, and the atomization micro-mist is ejected from top to bottom.
